(19) United States
(12) Patent Application Publication
(10) Pub. No.: US 2007/0126115 A1
(43) Pub. Date: Jun. 7, 2007

(54) Package substrate

(76) Inventors: Manabu Yanagihara, Osaka (JP); Hiroaki Ueno, Osaka (JP); Yasuhiro Uemoto, Shiga (JP); Tsuyoshi Tanaka, Osaka (JP)

Correspondence Address: MCDERMOTT WILL & EMERY LLP, 600 13TH STREET, N.W., WASHINGTON, DC, 20005-3096, US

(21) Appl. No.: 11/593,617

(22) Filed: Nov. 7, 2006

(30) Foreign Application Priority Data
Dec. 1, 2005 (JP) 2005-348044

(51) Int. Cl. H01L 23/34

(52) U.S. Cl. 257/712

(57) ABSTRACT

A package substrate has a substrate body on which an electronic component is mounted. The substrate body is formed at its top or back surface with a diamond film, a diamond-like carbon film or a carbon film.

### CROSS-REFERENCE TO RELATED APPLICATIONS

The disclosure of Japanese Patent Application No. 2005-348044 filed on Dec. 1, 2005 including specification, drawings and claims is incorporated herein by reference in its entirety.

### BACKGROUND OF THE INVENTION

(1) Field of the Invention

The present invention relates to package substrates on which semiconductor chips or semiconductor packages are mounted.

(2) Description of Related Art

Diamond offers extremely high hardness, excellent wear resistance, excellent chemical stability, and high thermal conductivity. It has been expected that a diamond film will be applied to a protective film for semiconductor components while taking advantage of the above-mentioned properties. Diamond is a phase of carbon under high pressures and high temperatures, and therefore a technique for forming diamond films was not sufficiently established. However, in recent years, satisfactory diamond thin films have been able to be formed even at a relatively low temperature of 600° C. or less by plasma chemical vapor deposition (CVD), laser abrasion or any other method. Diamond-like thin films are usually each composed of a crystalline part and an amorphous part and have various names according to the ratios of their components. In general, a diamond-like thin film whose crystalline part is smaller than its amorphous part and which exhibits low crystallinity is referred to as an amorphous carbon film or a graphite film, a diamond-like thin film whose crystalline part is larger than its amorphous part and which exhibits high crystallinity is referred to as a diamond-like carbon (DLC) film, and a diamond-like thin film exhibiting higher crystallinity than the DLC film is referred to as a diamond film. The thermal conductivity of each of such films varies according to the crystallinity thereof. An amorphous carbon film has a thermal conductivity of approximately 500 W/m·K, a DLC film has a thermal conductivity of approximately 1000 W/m·K, and a diamond film has a thermal conductivity of approximately 2000 W/m·K. These values are higher even than the thermal conductivity of copper, i.e., 390 W/m·K, and that of aluminum, i.e., 236 W/m·K and sufficiently higher than the thermal conductivity of insulative silicon dioxide (SiO₂), i.e., 1.4 W/m·K, that of epoxy resin used for plastic packages, i.e., 0.5 W/m·K, that of thermally conductive resin used for printed wiring boards or the like, i.e., 3 W/m·K, and that of alumina used for package substrates and packages, i.e., approximately 30 W/m·K.

Meanwhile, nitride-based semiconductors typified by gallium nitride (GaN) and wide band-gap semiconductors, such as silicon carbide (SiC), have been actively researched and developed as materials of semiconductor devices. One of the advantages of wide band-gap semiconductors is that the dielectric breakdown voltage of wide band-gap semiconductors is an order of magnitude larger than that of Si. When silicon is used for a semiconductor device as before, a drift layer through which electrons travel needs to be long in order to provide a high-breakdown-voltage power transistor. On the other hand, when a wide band-gap semiconductor is used for semiconductor devices, semiconductor devices each having a short drift layer (whose length is approximately one-tenth that of the drift layer in the case of semiconductor devices using Si) also have a breakdown voltage equal to that of semiconductor devices using Si. A drift layer serves as a resistive layer under consideration of the passage of current through semiconductor devices. Therefore, the shorter a drift layer of a semiconductor device is, the smaller the on-resistance of the semiconductor device becomes. When the mobility of semiconductors is approximately equivalent to the permittivity thereof, the on-resistance is inversely proportional to the third power of the strength of a dielectric breakdown electric field in terms of mathematical expressions. When the present inventors actually prototyped a power field-effect transistor (FET) made of GaN, the power FET exhibits an on-resistance of 19 mΩ under a breakdown voltage of 350 V (see, for example, IEEE Trans. Electron Devices, vol. 52, No. 9, pp. 1963-1968, 2005). The value of the on-resistance is one-half to one-fifth that of a known high-power MOSFET. More particularly, instead of use of a plurality of known Si power devices in parallel, use of a single GaN device or a single SiC device can provide the equivalent on-resistance. When the on-resistance is reduced without changing the number of devices, this can suppress the consumed power (heat generation).

Furthermore, one of the advantages of wide band-gap semiconductor devices is that while the maximum semiconductor junction temperature of Si semiconductor devices is approximately 150° C., wide band-gap semiconductor devices can operate at higher temperatures. FIG. 7 illustrate results obtained by the present inventors' comparison of the current-voltage characteristics of a FET using GaN as a material of a channel of the FET between room temperature and 300° C. Although the amount of current is seen to be smaller under a temperature of 300° C. than that under room temperature, the transistor operation can be recognized. Under such conditions, the current and breakdown voltage necessary for switching operations are secured.

In view of the above, if package substrates for GaN and SiC devices are developed based on a different standard from known Si devices under consideration of heat resistance and heat dissipation properties, package substrates will be able to become compact and lightweight.

A description will be given now of a case where high-power transistors formed of silicon (Si) are mounted on a package substrate as a first known example of a package substrate with reference to FIG. 8. FIG. 8 illustrates a known example in which a power transistor is assembled into an insertion-type package 101, such as T0-220, and the package 101 is mounted to a package substrate (printed wiring board) 104. The package 101 is brought into close contact with a heat sink 105 using silicon grease and a screw 103. A high-thermal-conductivity metal, such as aluminum and copper, is used for the heat sink 105. As illustrated by the arrows in FIG. 8, heat from the power transistor travels through the package 101 to the heat sink 105 and then spreads over the heat sink 105.

Next, a description will be given now of a case where a low-power transistor formed of Si is mounted on a package substrate as a second known example with reference to FIG. 9. FIG. 9 illustrates a known example in which a power transistor is assembled into a surface-mount package 201 and the surface-mount package 201 is mounted on a package substrate (printed wiring board) 203. A heat sink 204 is adhered to the back surface of the package substrate 203 by an adhesive. As illustrated by the arrows in FIG. 9, heat from the power transistor transfers through the package 201 to the heat sink 204. Such a package substrate provided at its back surface with a heat sink is disclosed in, for example, Japanese Unexamined Patent Publication No. 8-111568.

However, the structure of the package substrate of the first known example is unfit for reduction in the size and weight of electronic devices. The reason for this is that the heat sink 105 is tall and heavy. Furthermore, although the above structure is convenient in terms of heat dispersion, the packing density of electronic components has an upper limit. The reason for this is that a heat sink is attached directly to an insertion-type package, such as a T0-220 package.

Meanwhile, in the second known example, the surface-mount package is used. In this case, heat is dissipated through the package substrate to the heat sink. As described above, even when a thermally conductive resin is used as a material of the package substrate, the package substrate has a lower thermal conductivity than a metal. Therefore, the heat resistance of the package substrate becomes higher than that of the first known example. Consequently, available power devices are limited.

### SUMMARY OF THE INVENTION

An object of the present invention is to reduce the weight and size of a package substrate on which a power device chip is mounted or a package substrate to which a power device package is attached.

In order to achieve the above-mentioned object, a package substrate of the present invention uses one of a diamond film, a diamond-like carbon film and a carbon film to improve its heat dissipation. In particular, when a power device using a nitride semiconductor or SiC is packaged as a semiconductor device, the package substrate can be significantly reduced in size.

Furthermore, a through hole may be formed in the package substrate. This facilitates dissipating heat to the back surface of the package substrate. The package substrate may be formed with a projection to increase its surface area. This facilitates dissipating heat.

Moreover, a nitride-based semiconductor device or a SiC device that can have a junction temperature exceeding 150° C., i.e., the upper limit of the junction temperature of a Si device, may be used as a semiconductor device to be mounted on the package substrate. This can significantly reduce the size and weight of the package substrate as compared with a known package substrate on which a Si device is mounted.

Disclosed in Japanese Unexamined Patent Publication No. 5-63121 is an electronic component having a subassembly or seal formed with a diamond film to improve its electrical and thermal properties. However, in this publication, a description is not given of a specific name of the electronic component and a method for achieving the electronic component. Use of a diamond film, a diamond-like carbon film or a carbon film for a package substrate and a specific structure of the package substrate are disclosed in the present application for the first time.

In view of the above, the present invention provides a package substrate that can be reduced in size by improving its heat dissipation.

### BRIEF DESCRIPTION OF THE DRAWINGS

FIG. 1 is a cross-sectional view illustrating a package substrate according to a first embodiment of the present invention.

FIG. 2 is a cross-sectional view illustrating a package substrate according to a second embodiment of the present invention.

FIG. 3 is a cross-sectional view illustrating a package substrate according to a third embodiment of the present invention.

FIG. 4 is a cross-sectional view illustrating a package substrate according to a fourth embodiment of the present invention.

FIG. 5 is a cross-sectional view illustrating a package substrate according to a fifth embodiment of the present invention.

FIG. 6 is a cross-sectional view illustrating a package substrate according to a sixth embodiment of the present invention.

FIG. 7 is a graph illustrating the current-voltage (I-V) characteristics of a GaN-FET at room temperature and 300° C.

FIG. 8 is a cross-sectional view illustrating a package substrate of a first known example on which a power device assembled into an insertion-type package is mounted.

FIG. 9 is a cross-sectional view illustrating a package substrate of a second known example on which a power device assembled into a surface-mount package is mounted.

### DETAILED DESCRIPTION OF THE INVENTION

Transistors according to embodiments of the present invention will be described with reference to the drawings.

### EMBODIMENT 1

FIG. 1 is a cross-sectional view illustrating a package substrate on which a packaged semiconductor device is mounted according to a first embodiment of the present invention. A 3-μm-thick diamond film 13 is formed on an insulative substrate 14, and a surface-mount power transistor 11 including an electrically active layer formed of GaN is mounted thereon. Although not shown, leads 12 are soldered onto a wiring pattern on the diamond film 13 using a cream solder. Paths through which heat is dissipated are illustrated by the arrows in FIG. 1. As illustrated by the arrows, heat is dissipated not only through a heat sink 15 adhered to the back surface of the substrate as before but also through the top and back surfaces of the package substrate each having a large area.

The thicker the diamond film 13 is, the better. However, when it is too thick, this causes a break in the diamond film 13. Therefore, the diamond film 13 preferably has a thickness of approximately 0.5 μm through 5 μm.

### EMBODIMENT 2

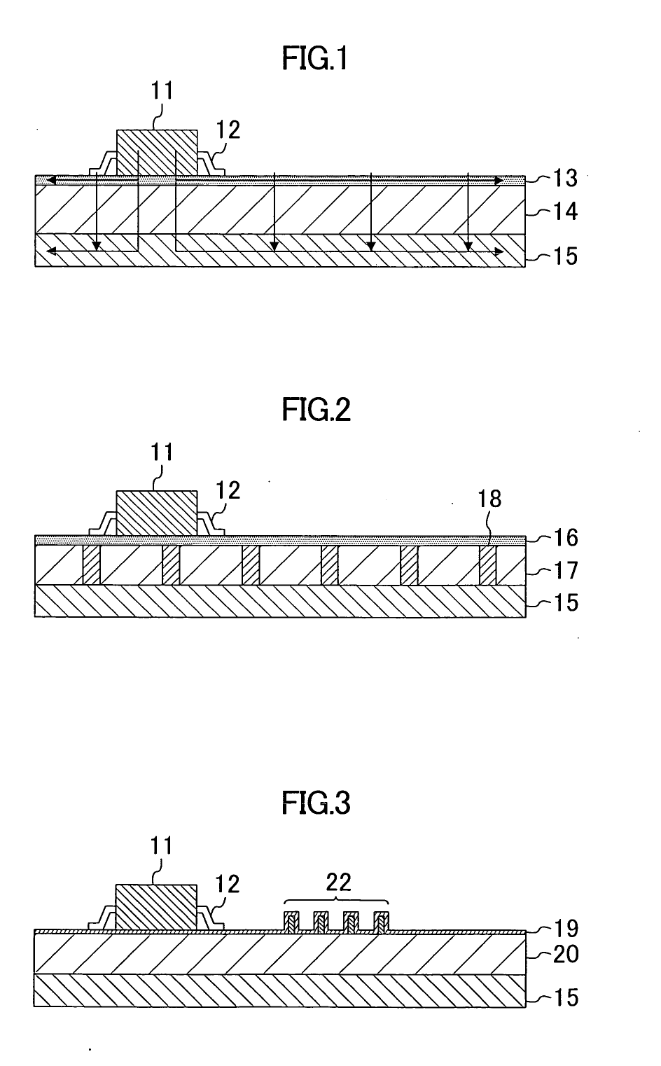

FIG. 2 is a cross-sectional view illustrating a package substrate on which a packaged semiconductor device is mounted according to a second embodiment of the present invention. The configuration of the package substrate of the second embodiment is mostly similar to that of the first embodiment. However, unlike the first embodiment, through holes 18 are formed in a package substrate 17 so as to be filled with diamond. Heat spreading over the diamond film 16 efficiently diffuses into a heat sink 15, resulting in a reduction in heat resistance.

A substance with which the through holes 18 are filled is not limited to diamond but needs to be any one of substances having a sufficiently higher thermal conductivity than a material of the package substrate 17. The substances include gold or copper.

### EMBODIMENT 3

FIG. 3 is a cross-sectional view illustrating a package substrate on which a packaged semiconductor device is mounted according to a third embodiment of the present invention. An insulative substrate 20 is formed with projections 22 to increase its surface area. A diamond film 19 is entirely formed to cover the substrate 20 and projections 22. This structure improves heat dissipation into air, resulting in a reduction in heat resistance.

### EMBODIMENT 4

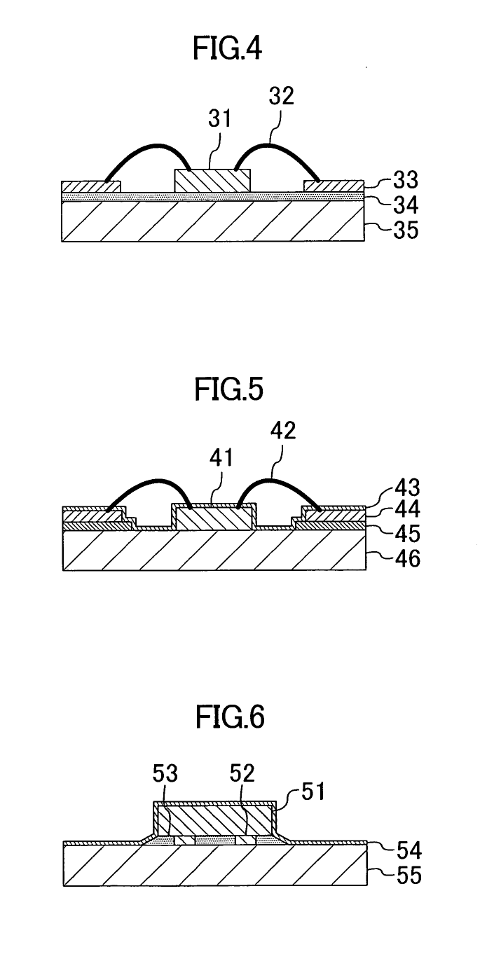

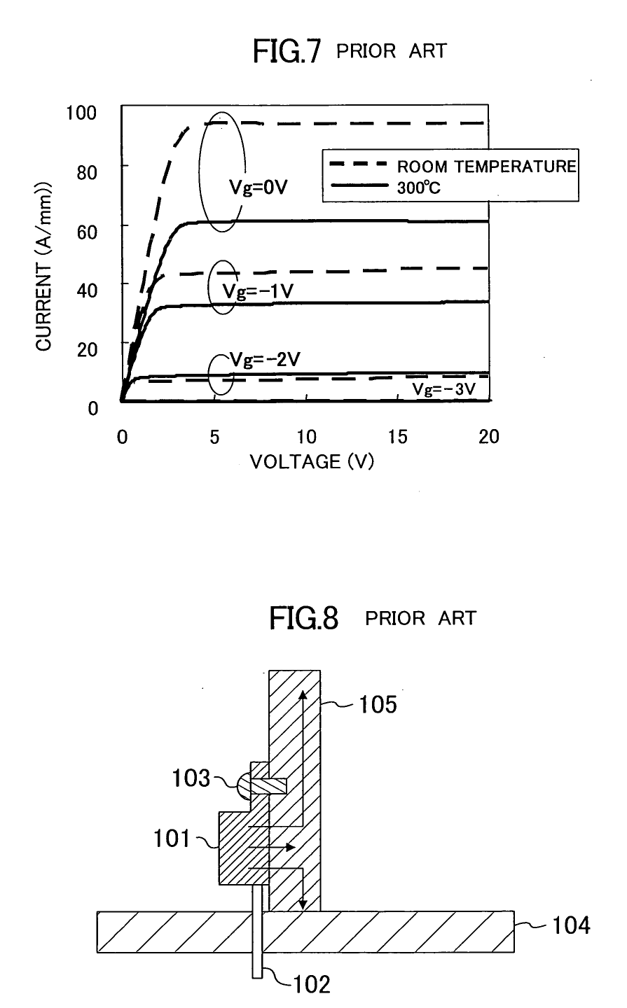

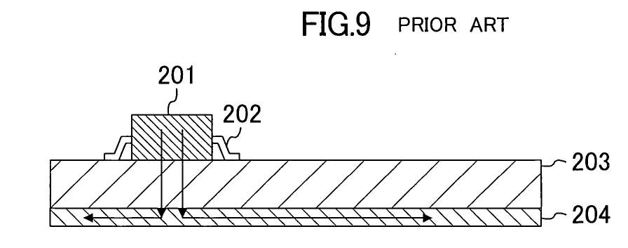

FIG. 4 is a cross-sectional view illustrating a package substrate on which a semiconductor chip is mounted according to a fourth embodiment of the present invention. A semiconductor chip 31 including an electrically active layer formed of GaN is mounted on an insulative substrate 35 formed at its top surface with a diamond thin film 34. Leads 33 are formed on the diamond thin film 34 and connected through gold wires 32 to the semiconductor chip 31. Heat from the semiconductor chip 31 transfers through the diamond thin film 34 and the top surface of the insulative substrate 35 to the back surface of the substrate 35 and is dissipated principally from the back surface thereof.

### EMBODIMENT 5

FIG. 5 is a cross-sectional view illustrating a package substrate on which a semiconductor chip is mounted according to a fifth embodiment of the present invention. A semiconductor chip 41 including an electrically active layer formed of GaN is mounted on a conductive substrate 46. Insulators 45 are adhered onto the conductive substrate 46, and leads 44 are formed on the insulators 45. The semiconductor chip 41 is connected through gold wires 42 to the leads 44. Then, a 3-μm-thick diamond thin film 43 is entirely formed on the conductive substrate 46. Heat from the semiconductor chip 41 travels not only toward the back surface of the conductive substrate 46 but also through the diamond thin film 43 located on the top surface thereof to the top surface thereof and spreads over the top surface thereof. Then, the spread heat is dissipated.

### EMBODIMENT 6

FIG. 6 is a cross-sectional view illustrating a package substrate on which a semiconductor chip is mounted according to a sixth embodiment of the present invention. A semiconductor chip 51 including an electrically active layer formed of GaN is mounted on the top surface of an insulative substrate 55 by flip-chip bonding using gold bumps 52 such that its active side is opposed thereto. Under such conditions, an approximately 3-μm-thick diamond thin film 54 is entirely formed on the insulative substrate 55. Heat generated by the semiconductor chip 51 travels through the back surface of the chip 51 toward the diamond thin film 54 and spreads over the diamond thin film 54. The spread heat is dissipated into air or to the insulative substrate 55.

As described above, since the package substrate of the present invention achieves a reduction in its weight and size, the package substrate is applicable to various types of electronic devices.

What is claimed is:

1. A package substrate comprising a substrate body on which an electronic component is mounted,
at least one of the top and back surfaces of the substrate body being formed with one of a diamond film, a diamond-like carbon film and a carbon film.

2. The package substrate of claim 1, wherein
a through hole is formed in the substrate body so as to be filled with a substance having a higher thermal conductivity than a main constituent of the substrate body.

3. The package substrate of claim 1, wherein
a heat sink is formed on the back surface of the substrate body.

4. The package substrate of claim 1, wherein
said one of the diamond film, the diamond-like carbon film and the carbon film has a thickness of 0.5 μm through 5 μm both inclusive.

5. The package substrate of claim 1, wherein
the electronic component is a semiconductor device, and the junction temperature of the semiconductor device under operating conditions exceeds 150° C.

6. The package substrate of claim 1, wherein
the electronic component is a semiconductor device including an electrically active layer made of a nitride-based semiconductor or a silicon carbide semiconductor.

7. A package substrate comprising a substrate body on which an electronic component is mounted,
one of the top and back surfaces of the substrate body being partially formed with a projection for increasing the surface area of the substrate body, and
the projection being covered with one of a diamond film, a diamond-like carbon film and a carbon film.

8. The package substrate of claim 7, wherein
a heat sink is formed on the back surface of the substrate body.

9. The package substrate of claim 7, wherein
said one of the diamond film, the diamond-like carbon film and the carbon film has a thickness of 0.5 μm through 5 μm both inclusive.

10. The package substrate of claim 7, wherein
the electronic component is a semiconductor device, and the junction temperature of the semiconductor device under operating conditions exceeds 150° C.

11. The package substrate of claim 7, wherein
the electronic component is a semiconductor device including an electrically active layer made of a nitride-based semiconductor or a silicon carbide semiconductor.

12. A package substrate comprising a substrate body on which an electronic component is mounted,
one of a diamond film, a diamond-like carbon film and a carbon film being continuously formed to cover the electronic component and the substrate body.

13. The package substrate of claim 12, wherein
the electronic component is a semiconductor chip, and
the semiconductor chip is mounted on the substrate body by flip-chip bonding.

14. The package substrate of claim 12, wherein
a heat sink is formed on the back surface of the substrate body.

15. The package substrate of claim 12, wherein
said one of the diamond film, the diamond-like carbon film and the carbon film has a thickness of 0.5 μm through 5 μm both inclusive.

16. The package substrate of claim 12, wherein
the electronic component is a semiconductor device, and the junction temperature of the semiconductor device under operating conditions exceeds 150° C.

17. The package substrate of claim 12, wherein
the electronic component is a semiconductor device including an electrically active layer made of a nitride-based semiconductor or a silicon carbide semiconductor.
